(19) United States
(12) Patent Application Publication
(10) Pub. No.: US 2010/0127767 A1
(43) Pub. Date: May 27, 2010

(54) Integrated Circuit Device Including Noise Filter

(76) Inventors: Eui Seung Kim, Suwon-si (KR); Yong Hee An, Hwasung-si (KR); Jung-Chan Kim, Yongin-si (KR)

Correspondence Address: F. CHAU & ASSOCIATES, LLC, 130 WOODBURY ROAD, WOODBURY, NY, 11797, US

(21) Appl. No.: 12/626,138

(22) Filed: Nov. 25, 2009

(30) Foreign Application Priority Data
Nov. 27, 2008 (KR) 10-2008-0118721

(51) Int. Cl. H03K 5/00

(52) U.S. Cl. 327/551

(57) ABSTRACT

An integrated circuit (IC) device is provided. The IC device includes a detector configured to detect an abnormal condition of the IC device and to generate a detection result as an attack signal, and a noise filter configured to filter out the attack signal as noise and to generate a filtered attack signal. The noise filter is configured to filter out the attack signal as noise when the attack signal is not maintained at a first logic level for a reference period and to generate the filtered attack signal when the attack signal is maintained at the first logic level for the reference period.

### CROSS-REFERENCE TO RELATED APPLICATION

This application claims under 35 U.S.C. §119 priority to and the benefit of Korean Patent Application No. 10-2008-0118721 filed on Nov. 27, 2008, in the Korean Intellectual Property Office, the entire content of which is incorporated by reference herein.

### BACKGROUND

1. Technical Field

The present inventive concept relates to an integrated circuit (IC) device, and more particularly, to an IC device including a noise filter.

2. Discussion of the Related Art

IC cards or smart cards include detectors for detecting abnormal conditions, e.g., abnormal voltage, abnormal frequency, abnormal temperature, glitch, and abnormal light exposure, respectively. When at least one detector among those detectors detects an abnormal condition and outputs a detection signal as a detection result, all circuits including a central processing unit (CPU) included in the smart cards are reset in response to the detection signal, so that the smart cards can protect data from being leaked, destroyed, or corrupted by external attacks.

### SUMMARY

Exemplary embodiments of the present inventive concept provide an integrated circuit (IC) device for filtering out noise from an attack signal generated by a detector.

In accordance with an exemplary embodiment an integrated circuit (IC) device includes a detector configured to detect an abnormal condition of the IC device and to generate a detection result as an attack signal, and a noise filter configured to filter out the attack signal as noise and to generate a filtered attack signal. The noise filter is configured to filter out the attack signal as noise when the attack signal is not maintained at a first logic level for a reference period and to generate the filtered attack signal when the attack signal is maintained at the first logic level for the reference period.

The noise filter may count the number of pulses of a clock signal while the attack signal is at the first logic level, compare a count result with a reference value, and generate the filtered attack signal based upon a comparison result.

The noise filter may include a counter configured to perform counting with respect to the attack signal at the first logic level based upon the clock signals, and a comparator configured to compare a count result of the counter with the reference value.

In accordance with an exemplary embodiment an integrated circuit (IC) device includes a detector configured to detect an abnormal condition of the IC device and to generate a detection result as an attack signal and a noise filter unit configured to filter out noise from the attack signal and to generate a filtered attack signal. The noise filter unit is configured to count the number of ripples of the attack signal, to compare a count result with a reference value, and to generate the filtered attack signal based upon a comparison result.

The count result of the noise filter unit may be reset when the attack signal is maintained at a first logic level during a reference period.

The first logic level may be indicative of no attack signal.

The noise filter unit may include an attack signal filtering block configured to count the number of ripples of the attack signal, to compare the count result with the reference value, and to generate the filtered attack signal based upon the comparison result, and a reset block configured to generate a noise reset signal when the attack signal is at a first logic level during a reference period. The attack signal filtering block resets the count result based upon the noise reset signal.

The attack signal filtering block may include a first logic unit configured to receive and to perform a logic operation on the attack signal, a clock signal, and a signal inverting a filtered attack signal, and a noise filter configured to count the number of ripples of an output signal of the first logic unit, to compare the count result with the reference value, and to generate the filtered attack signal based upon the comparison result.

The reset block may include a second logic unit configured to receive and perform a logic operation on a system reset signal, an inverted attack signal, and an inverted filter reset signal, and a filter reset signal generator configured to generate a filter reset signal when an output signal of the second logic unit is maintained at the first logic level for the reference period.

The reset block may further include a third logic unit configured to receive and to perform a logic operation on the system reset signal and the inverted filter reset signal.

According to an exemplary embodiment a smart card is provided. A CPU controls operations of the smart card. An interface communicates data with an external data processing device. A memory performs write, read, or verify operations in response to control signals output from the CPU. Peripheral circuitry processes data to and from the memory. An attack signal detector detects an abnormal condition of the smart card, generates a detection result as an attack signal, filters out noise from the attack signal, and outputs a filtered attack signal. The attack signal detector is configured to filter out the attack signal as noise when the attack signal is not maintained at a first logic level for a reference period and generate the filtered attack signal when the attack signal is maintained at the first logic level for the reference period.

The smart card may further include a security handler that receives the filtered attack signal from the attack signal detector and that transmits the filtered attack signal to at least one among the interface, the CPU, the peripheral circuit, the memory, and the reset controller through a bus.

The smart card may further include a reset controller that receives the filtered attack signal from the attack signal detector and that determines whether to reset the entire smart card or some portions of the smart card based upon the filtered attack signal.

The smart card may be in an electronic system which includes at least one of a video camera, a television, an MP3 player, a game console, an electronic instrument, a portable terminal, a personal computer, a personal digital assistant, a voice recorder and a personal computer card.

According to an exemplary embodiment a smart card is provided. A CPU controls operations of the smart card. An interface that communicates data between the smart card and an external data processing device. A memory performs write, read, or verify operations in response to control signals output from the CPU. Peripheral circuitry processes data output to and from the memory. An attack signal detector detects an abnormal condition of the smart card, generates a detection result as an attack signal, filters out noise from the attack signal, and outputs a filtered attack signal. The attack signal detector is configured to count the number of ripples of the attack signal, to compare a count result with a reference value, and to generate the filtered attack signal based upon a comparison result.

### BRIEF DESCRIPTION OF THE DRAWINGS

The details of the present inventive concept will become more apparent by the description of exemplary embodiments thereof with reference to the attached drawings in which:

FIG. 1 is a block diagram of an integrated circuit (IC) device according to an exemplary embodiment of the present inventive concept;

FIG. 2 is a block diagram of a noise filter illustrated in FIG. 1;

FIG. 3 is a diagram for explaining a procedure in which the IC device illustrated in FIG. 1 filters out noise;

FIG. 4 is a diagram for explaining the operation of the IC device illustrated in FIG. 1;

FIG. 5 is a block diagram of an IC device according to an exemplary embodiment of the present inventive concept;

FIG. 6 is a block diagram of a noise filter illustrated in FIG. 5;

FIG. 7 is a diagram for explaining the counting operation of a counter illustrated in FIG. 5;

FIG. 8 is a block diagram of a filter reset signal generator illustrated in FIG. 5;

FIG. 9 is a block diagram of a smart card according to an exemplary embodiment of the present inventive concept;

FIGS. 10A, 10B and 10C are diagrams for explaining a procedure in which the smart card illustrated in FIG. 9 processes an attack signal;

FIGS. 11A, 11B, 11C, 11D, 11E, 11F, 11G, 11H, 11I and 11J are diagrams of the examples of an electronic system according to an exemplary embodiment of the present inventive concept;

FIG. 12 is a flowchart of a noise filtering method according to an exemplary embodiment of the present inventive concept; and

FIG. 13 is a flowchart of a noise filtering method according to an exemplary embodiment of the present inventive concept.

### DETAILED DESCRIPTION OF THE EMBODIMENTS

The present inventive concept may be embodied in many different forms and should not be construed as limited to the embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present.

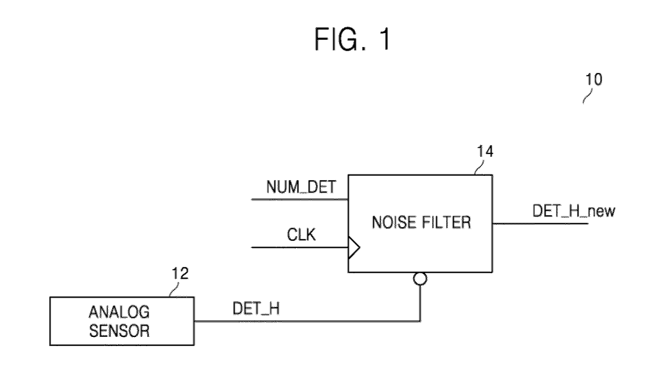

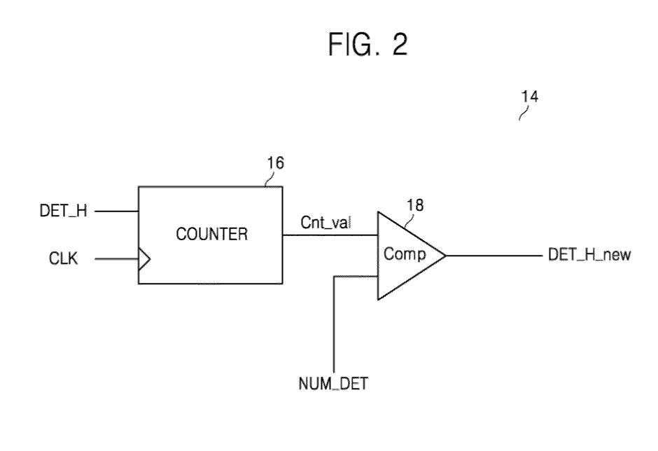

FIG. 1 is a block diagram of an integrated circuit (IC) device 10 according to an exemplary embodiment of the present inventive concept. FIG. 2 is a block diagram of a noise filter 14 illustrated in FIG. 1. Referring to FIG. 1, the IC device 10 includes a detector (or a sensor or an analog sensor) 12 and a noise filter 14.

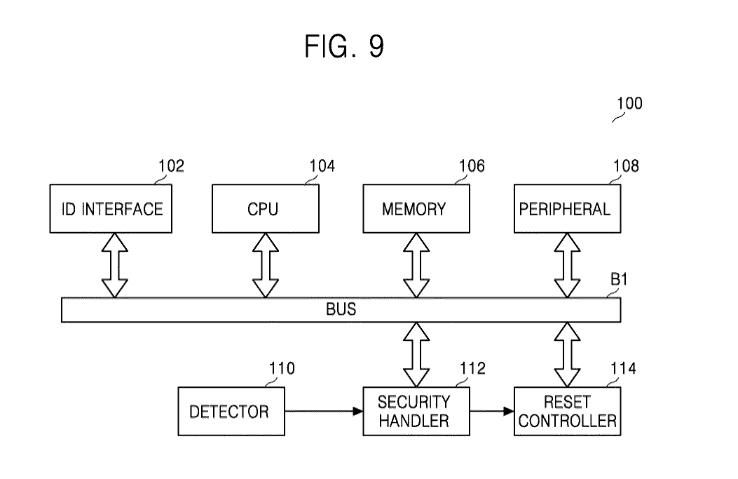

The IC device 10 is provided to detect an attack signal DET_H. The IC device 10 may be implemented in a smart card 100 (e.g., as shown in FIG. 9). In the exemplary embodiment shown in FIG. 9 the IC device 10 is depicted as a separate attack signal detector 110. However, IC device 10 may be implemented as part of at least one amongst an interface 102, a central processing unit (CPU) 104, a memory 106, a peripheral circuit 108, a security handler 112, or a reset controller 114.

Referring back to FIG. 1, the analog sensor/detector 12 detects an abnormal condition of the IC device 10 and generates a detection result as the attack signal DET_H. In more detail, the analog sensor/detector 12 detects an abnormal condition, e.g., abnormal voltage, abnormal frequency, abnormal temperature, glitch, or abnormal light exposure, of the IC device 10 and generates the detection result as the attack signal DET_H. The analog sensor/detector 12 may also detect a signal directly transmitted to the IC device 10 from an attacker attempting to retrieve data stored in the IC device 10 and output it as the attack signal DET_H.

In other words, the attack signal DET_H is a signal corresponding to an abnormal condition of the IC device 10. When the attack signal DET_H is generated, all circuits, as well as a CPU (not shown), included in the IC device 10 can be reset, so that the IC device 10 can protect data from being leaked, destroyed, or corrupted by an external attack.

The noise filter 14 filters out noise from the attack signal DET_H and thus generates a filtered attack signal DET_H_new. The noise is a signal hindering the detection of the attack signal DET_H. The attack signal DET_H may be distorted by the noise. The noise filter 14 may filter out as the noise an attack signal DET_H that is not maintained at a first logic level (e.g., a high level of “1”) for a reference period.

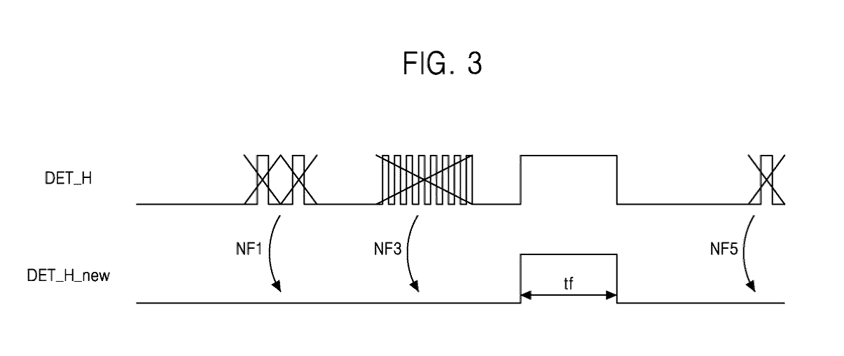

FIG. 3 is a diagram for explaining the procedure by which the IC device 10 illustrated in FIG. 1 filters out noise. Referring to FIGS. 1 and 3, when the attack signal DET_H is not maintained at the first logic level, i.e., the high level of “1” for a reference period “tf”, the noise filter 14 determines the attack signal DET_H to be noise and filters out the attack signal DET_H. For instance, the noise filter 14 may determine the attack signal DET_H such as NF1, NF3, or NF5 that is not maintained at the first logic level, i.e., the high level of “1” for the reference period “tf” as noise, ignore it, and output the noise determined attack signal DET_H at a second logic level, e.g., a low level of “0”.

Referring back to FIGS. 1 and 2, the noise filter 14 counts the number of pulses of a clock signal CLK while the attack signal DET_H is maintained at the first logic level, i.e., the high level of “1”, compares a count result Cnt_val with a reference value NUM_DET, and outputs the filtered attack signal DET_H_new based upon a comparison result. The noise filter 14 includes a counter 16 and a comparator 18.

The counter 16 performs counting with respect to the attack signal DET_H at the first logic level, i.e., the high level of “1” based upon the clock signal CLK. The comparator 18 compares the count result Cnt_val of the counter 16 with the reference value NUM_DET and outputs the comparison result as the filtered attack signal DET_H_new. For instance, the comparator 18 may output the filtered attack signal DET_H_new at the first logic level, i.e., the high level of “1” when the count result Cnt_val is greater than the reference value NUM_DET. When the count result Cnt_val is less than the reference value NUM_DET, the comparator 18 may output the filtered attack signal DET_H_new at the second logic level, i.e., the low level of “0”.

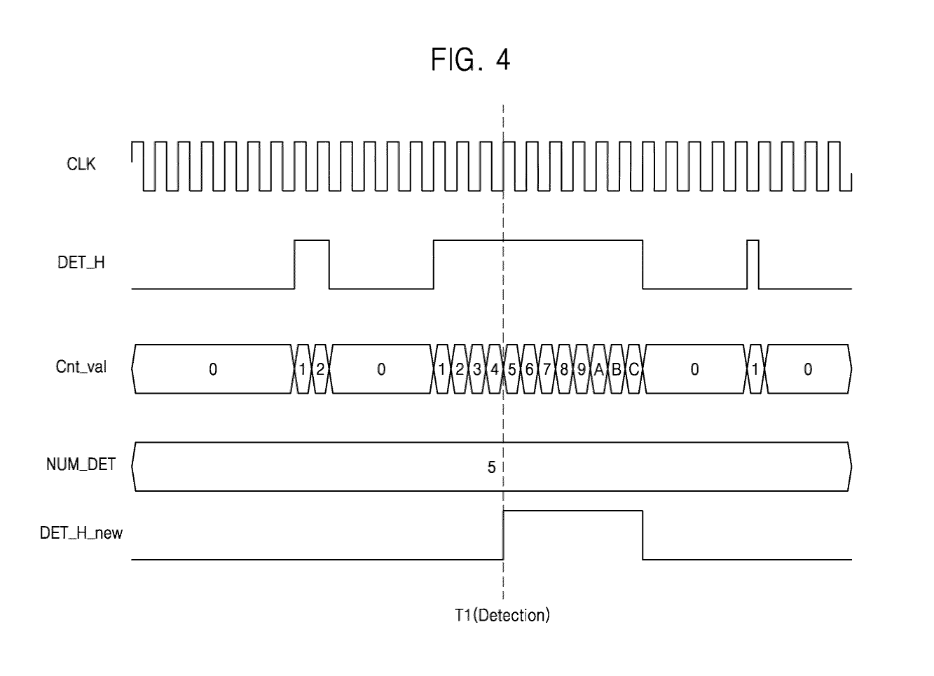

FIG. 4 is a diagram for further explaining the operation of the IC device 10 illustrated in FIG. 1. Referring to FIGS. 1, 2, and 4, when the reference value NUM_DET is 5 cycles or clocks, the counter 16 counts the number of cycles of the clock signal CLK while the attack signal DET_H is at the first logic level, i.e., the high level of “1” and outputs the count result Cnt_val.

The comparator 18 outputs the filtered attack signal DET_H_new at the second logic level, i.e., the low level of “0” when the count result Cnt_val is less than the reference value NUM_DET (i.e., 5 cycles) and outputs the filtered attack signal DET_H_new at the first logic level, i.e., the high level of “1” when the count result Cnt_val is greater than the reference value NUM_DET (i.e., 5 cycles), that is, at a time point T1.

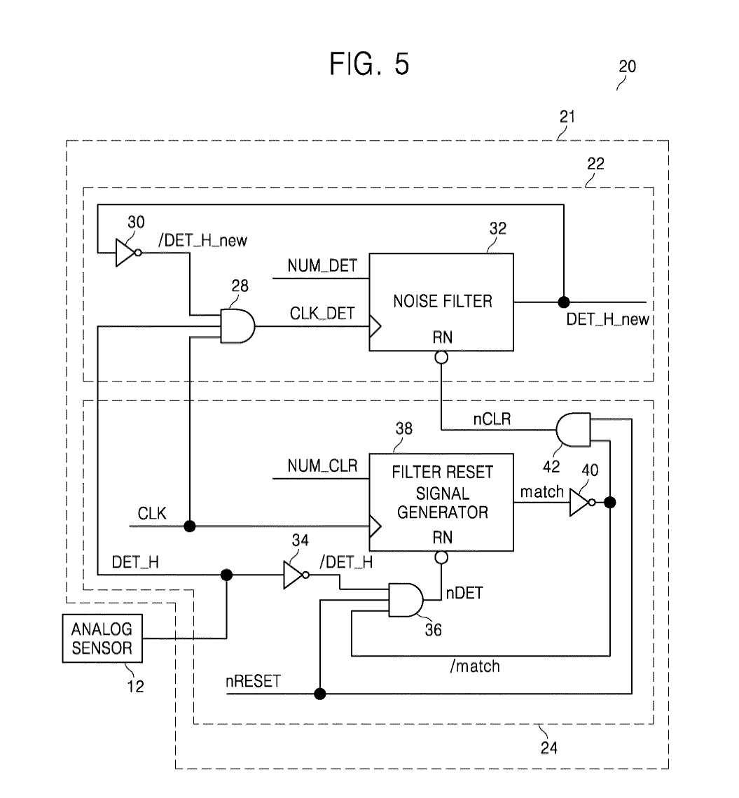

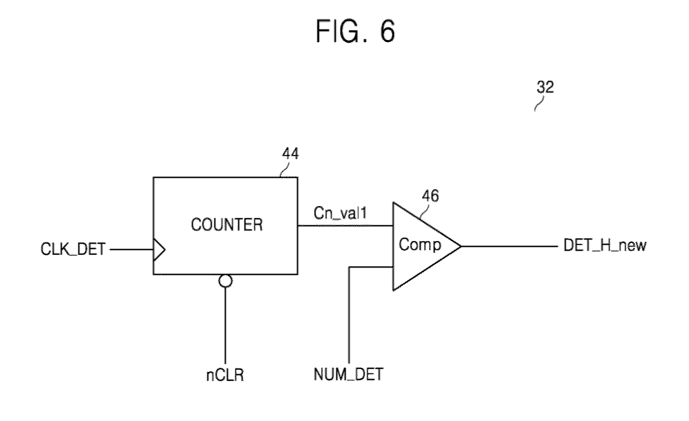

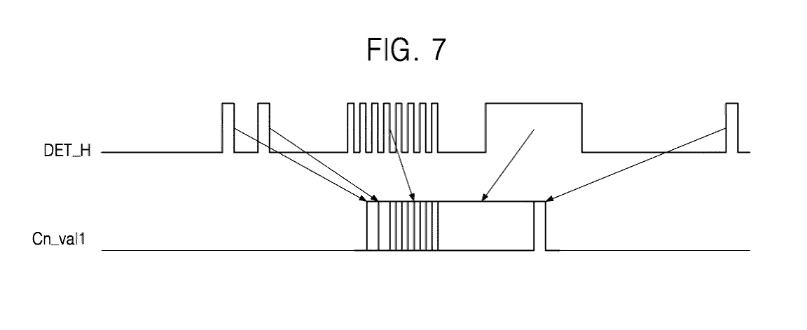

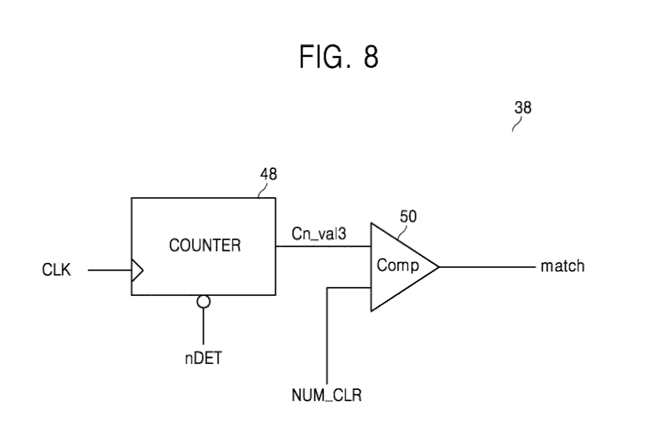

FIG. 5 is a block diagram of an IC device 20 according to an exemplary embodiment of the present inventive concept. FIG. 6 is a block diagram of a noise filter 32 illustrated in FIG. 5. FIG. 7 is a diagram for explaining the counting operation of a counter illustrated in FIG. 5. FIG. 8 is a block diagram of a filter reset signal generator 38 illustrated in FIG. 5. Referring to FIGS. 5 through 8, the IC device 20 includes the analog sensor/detector 12 and a noise filter unit 21. The IC device 20 may be implemented in a smart card 100 (e.g., as shown in FIG. 9). In the exemplary embodiment shown in FIG. 9 the IC device 20 is depicted as a separate attack signal detector 110. However, IC device 20 may be implemented as part of at least one amongst an interface 102, a central processing unit (CPU) 104, a memory 106, a peripheral circuit 108, a security handler 112, or a reset controller 114.

Referring back to FIG. 5, the analog sensor/detector 12 generates an attack signal DET_H. The analog sensor/detector 12 detects an abnormal condition, e.g., abnormal voltage, abnormal frequency, abnormal temperature, glitch, or abnormal light exposure, of the IC device 20 and generates the detection result as the attack signal DET_H. The analog sensor/detector 12 may also detect a signal directly transmitted to the IC device 10 from an attacker attempting to retrieve data stored in the IC device 20 and outputs it as the attack signal DET_H.

In other words, the attack signal DET_H is a signal corresponding to an abnormal condition of the IC device 20. When the attack signal DET_H is generated, all circuits, as well as a CPU (not shown), included in the IC device 20 can be reset, so that the IC device 20 can protect data from being leaked, destroyed, or corrupted by an external attack.

Referring to FIGS. 5 and 6, the noise filter unit 21 filters out noise from the attack signal DET_H output from the analog sensor/detector 12 and generates a filtered attack signal DET_H_new. At this time, the noise filter unit 21 counts the number of ripples of the attack signal DET_H, compares a count result Cn_val1 with a first reference value NUM_DET, and generates the filtered attack signal DET_H_new based upon a comparison result. In addition, the noise filter unit 21 resets the count result Cn_val1, for example, to “0”, when the attack signal DET_H is at a second logic level, e.g., a low level of “0”, for a predetermined reference period. The noise filter unit 21 includes an attack signal filtering block 22 and a reset block 24.

The attack signal filtering block 22 counts the number of ripples of the attack signal DET_H, compares the count result Cn_val1 with the first reference value NUM_DET, and generates the filtered attack signal DET_H_new based upon the comparison result. In addition, the attack signal filtering block 22 resets the count result Cn_val1, for example, to “0”, based upon a noise reset signal nCLR generated by the reset block 24. The attack signal filtering block 22 includes a first logic unit 28, a first inverter 30, and a noise filter 32.

The first logic unit 28 receives and performs a logic operation on the attack signal DET_H, a clock signal CLK, and an inverted signal of the filtered attack signal/DET_H_new (e.g., an output signal of the first inverter 30). The first logic unit 28 may be implemented by an AND gate or a logic circuit combining AND, OR, NAND, and/or NOR operations.

The first inverter 30 receives and inverts the filtered attack signal DET_H_new and outputs an inversion result/DET_H_new.

The noise filter 32 counts the number of ripples of an output signal CLK_DET of the first logic unit 28, compares the count result Cn_val1 with the first reference value NUM_DET, and generates the filtered attack signal DET_H_new based upon a comparison result. The noise filter 32 includes a first counter 44 and a first comparator 46 illustrated in FIG. 6.

The first counter 44 counts the number of ripples of the output signal CLK_DET of the first logic unit 28 and outputs the count result Cn_val1. The first counter 44 is reset in response to the noise reset signal nCLR generated by the reset block 24. For instance, the first counter 44 may accumulatively count the number of ripples of the output signal CLK_DET of the first logic unit 28 until the noise reset signal nCLR is generated, as illustrated in FIG. 7.

The first comparator 46 compares the count result Cn_val1 of the first counter 44 with the first reference value NUM_DET and outputs a comparison result as the filtered attack signal DET_H_new. For instance, the first comparator 46 may output the filtered attack signal DET_H_new at a first logic level, e.g., a high level of “1” when the count result Cn_val1 is greater than the first reference value NUM_DET and output the filtered attack signal DET_H_new at the second logic level, i.e., the low level of “0” when the count result Cn_val1 is less than the first reference value NUM_DET.

The reset block 24 generates the noise reset signal nCLR when the attack signal DET_H is at the second logic level, i.e., the low level of “0” for a predetermined reference period. The noise reset signal nCLR is provided to reset the attack signal filtering block 22 and the attack signal filtering block 22 resets the count result Cn_val1, e.g., to “0”, in response to the noise reset signal nCLR. The reset block includes a second inverter 34, a second logic unit 36, the filter reset signal generator 38, a third inverter 40, and a third logic unit 42.

The second inverter 34 receives and inverts the attack signal DET_H and outputs an inverted attack signal/DET_H.

The second logic unit 36 receives and performs a logic operation on a system reset signal nRESET, the inverted attack signal/DET_H, and an output signal/match of the third inverter 40. The second logic unit 36 may be implemented by an AND gate or a logic circuit combining AND, OR, NAND, and/or NOR operations.

The filter reset signal generator 38 generates a filter reset signal “match” when an output signal nDET of the second logic unit 36 is maintained at the second logic level, i.e., the low level of “0” for a predetermined reference period. The filter reset signal generator 38 includes a second counter 48 and a second comparator 50 illustrated in FIG. 8.

The second counter 48 performs counting with respect to the output signal nDET at the second logic level, i.e., the low level of “0” based upon the clock signal CLK. In more detail, the second counter 48 counts the number of ripples of the clock signal CLK while the output signal nDET of the second logic unit 36 is at the second logic level, i.e., the low level of “0” and outputs a count result Cn_val3. The second counter 48 is reset in response to the output signal nDET of the second logic unit 36. For instance, the second counter 48 may count the number of ripples of the clock signal CLK until the output signal nDET of the second logic unit 36 is generated at the first logic level, i.e., the high level of “1”.

The second comparator 50 compares the count result Cn_val3 of the second counter 48 with a second reference value NUM_CLR and outputs a comparison result, i.e., the filter reset signal “match”. For instance, the second comparator 50 may output the filter reset signal “match” at the first logic level, i.e., the high level of “1” when the count result Cn_val3 of the second counter 48 is greater than the second reference value NUM_CLR and output the filter reset signal “match” at the second logic level, i.e., the low level of “0” when the count result Cn_val3 of the second counter 48 is less than the second reference value NUM_CLR.

The third inverter 40 receives and inverts the filter reset signal “match” output from the filter reset signal generator 38 and outputs an inversion result/match.

The third logic unit 42 receives and performs a logic operation on the system reset signal nRESET and the output signal/match of the third inverter 40. The third logic unit 42 may be implemented by an AND gate or a logic circuit combining AND, OR, NAND, and/or NOR operations.

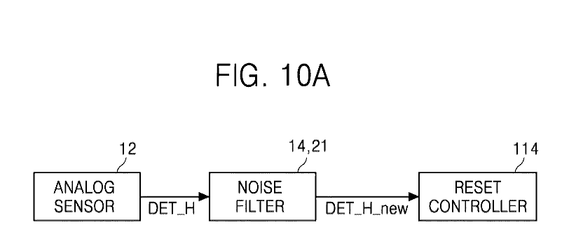

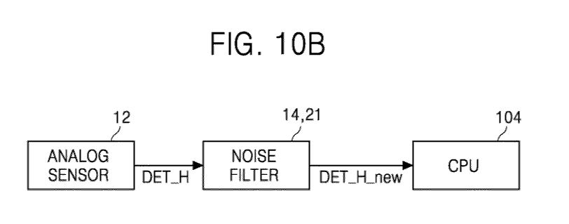

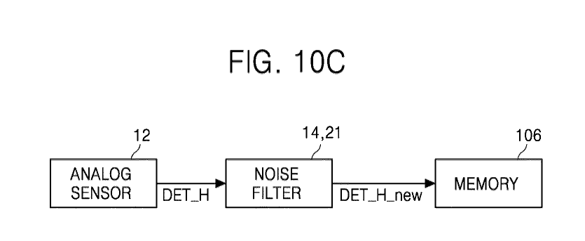

FIG. 9 is a block diagram of a smart card 100 according to an exemplary embodiment of the present inventive concept. FIGS. 10A through 10C are diagrams for explaining an exemplary procedure in which the smart card 100 illustrated in FIG. 9 may process an attack signal. Referring to FIGS. 1, 5, and 9 and FIGS. 10A through 10C, the smart card 100 includes the interface 102, the CPU 104, the memory 106, the peripheral circuit 108, the attack signal detector 110, the security handler 112, and the reset controller 114.

The interface 102 communicates data with an external data processing device (e.g., a host (not shown)). The CPU 104 controls the overall operations of the elements of the smart card 100, i.e., the interface 102, the memory 106, the peripheral circuit 108, the attack signal detector 110, the security handler 112, and the reset controller 114.

In addition, the CPU 104 may perform a fast interrupt request (FIQ) based upon a filtered attack signal DET_H_new generated by the attack signal detector 110 as illustrated in FIG. 10B. For instance, when the filtered attack signal DET_H new is generated, the CPU 104 may stop a current process and start a different routine, e.g., a system reboot. The CPU 104 also generates control signals (not shown) for controlling the program (or write), read, and/or verify operations of the memory 106.

The memory 106 performs the program (or write), read, or verify operation in response to a control signal output from the CPU 104. The memory 106 also stores information about abnormal conditions based upon the filtered attack signal DET_H_new generated by the attack signal detector 110 as illustrated in FIG. 10C.

The peripheral circuit 108 may include all circuits, e.g., a row decoder, a column decoder, and a write drive, necessary to write or program data output from the host to the memory 106. The peripheral circuit 108 may also include all circuits necessary to read or erase data stored in the memory 106.

As has been described in detail with reference to FIGS. 1 through 8, the attack signal detector 110 detects an abnormal condition, e.g., abnormal voltage, abnormal frequency, abnormal temperature, glitch, or abnormal light exposure, of the smart card 100, generates a detection result as the attack signal DET_H, filters out noise from the attack signal DET_H, and outputs the filtered attack signal DET_H_new. As mentioned previously exemplary embodiments the attack signal detector 110 may also be implemented in at least one among the interface 102, the CPU 104, the peripheral circuit 108, the attack signal detector 110, the security handler 112, and the reset controller 114.

The security handler 112 receives the filtered attack signal DET_H_new from the attack signal detector 110 and transmits it to at least one among the interface 102, the CPU 104, the peripheral circuit 108, the attack signal detector 110, and the reset controller 114 through a bus B1.

The reset controller 114 receives the filtered attack signal DET_H_new from the attack signal detector 110 as illustrated in FIG. 10A and determines whether to reset the entire smart card 100 or some elements of the smart card 100 based upon the filtered attack signal DET_H_new.

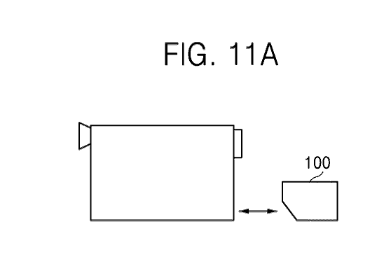

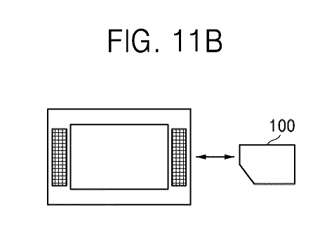

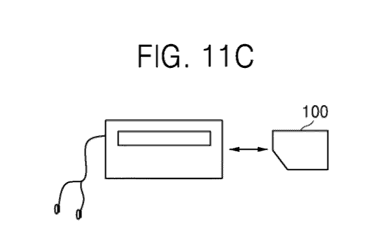

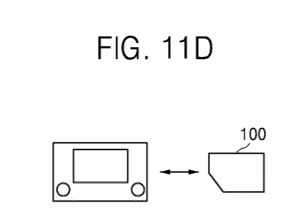

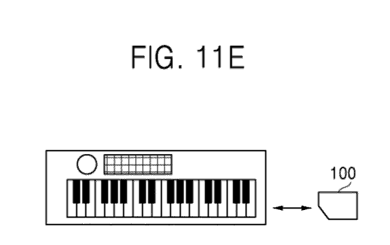

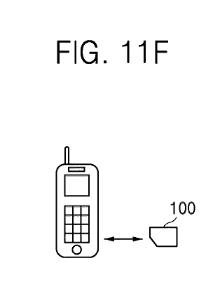

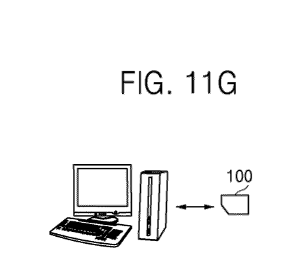

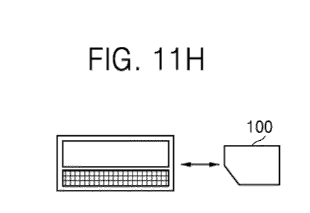

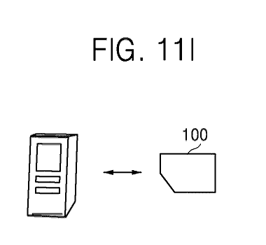

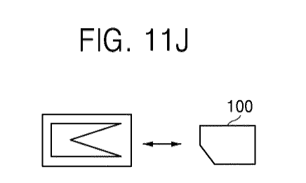

FIGS. 11A through 11J are diagrams of the examples of an electronic system according to an exemplary embodiment of the present inventive concept. Referring to FIGS. 11A through 11J, the electronic system includes the smart card 100 shown in FIG. 9 and a host (e.g., an electronic device). The electronic system may be a video camera shown in FIG. 11A, a television shown in FIG. 11B, an MP3 player shown in FIG. 11C, a game console shown in FIG. 11D, an electronic instrument shown in FIG. 11E, a portable terminal shown in FIG. 11F, a personal computer (PC) shown in FIG. 11G, a personal digital assistant (PDA) shown in FIG. 11H, a voice recorder shown in FIG. 11I, or a PC card shown in FIG. 11J.

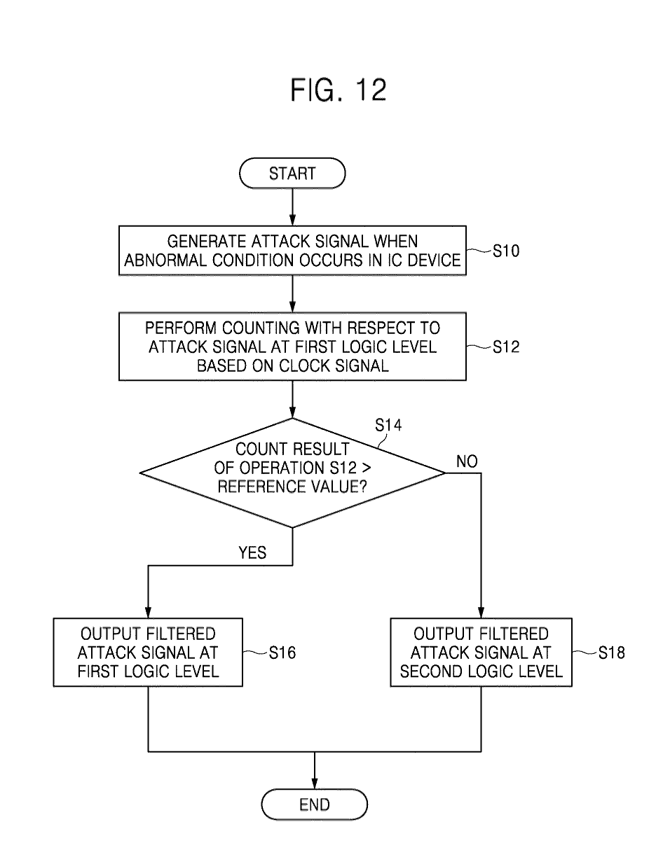

FIG. 12 is a flowchart of a noise filtering method according to an exemplary embodiment of the present inventive concept. Referring to FIGS. 1, 2, and 12, the analog sensor/detector 12 generates the attack signal DET_H when an abnormal condition occurs in the IC device 10 in operation S10.

The noise filter 14 performs counting with respect to the attack signal DET_H at the first logic level, i.e., the high level of “1” based upon the clock signal CLK in operation S12.

The noise filter 14 compares the count result Cnt_val obtained through operation S12 with the reference value NUM DET in operation S14. The noise filter 14 outputs the filtered attack signal DET_H_new at the first logic level, i.e., the high level of “1” when the count result Cnt_val is greater than the reference value NUM_DET in operation S16.

The noise filter 14 outputs the filtered attack signal DET_H_new at the second logic level, i.e., the low level of “0” when the count result Cnt_val is less than the reference value NUM_DET in operation S18.

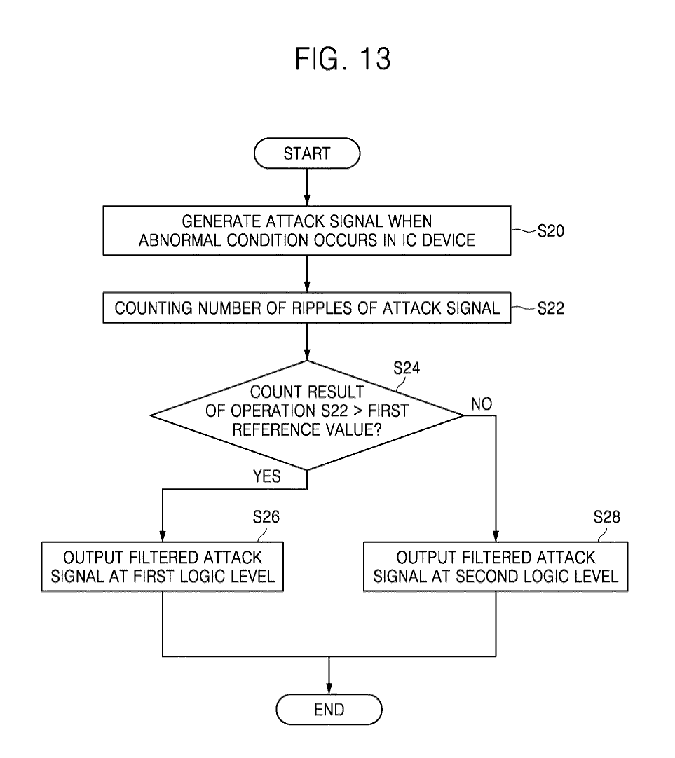

FIG. 13 is a flowchart of a noise filtering method according to other embodiments of the present inventive concept. Referring to FIGS. 5, 6, and 13, the analog sensor/detector 12 generates the attack signal DET_H when an abnormal condition occurs in the IC device 20 in operation S20.

The noise filter unit 21 counts the number of ripples of the attack signal DET_H in operation S22. The noise filter unit 21 compares the count result Cn_val1 obtained through operation S22 with the first reference value NUM_DET in operation S24.

When it is determined that the count result Cn_val1 is greater than the first reference value NUM_DET as a result of the comparison in operation S24, the noise filter unit 21 outputs the filtered attack signal DET_H_new at the first logic level, i.e., the high level of “1” in operation S26.

When it is determined that the count result Cn_val1 is less than the first reference value NUM_DET as a result of the comparison in operation S24, the noise filter unit 21 outputs the filtered attack signal DET_H_new at the second logic level, i.e., the low level of “0” in operation S28.

At this time, the noise filter unit 21 resets the count result Cn_val1, e.g., to “0”, when the attack signal DET_H is at the second logic level, i.e., the low level of “0” for a predetermined reference period.

As described above, according to an exemplary embodiment of the present inventive concept, an IC device including a noise filter can filter out noise from an attack signal. In addition, the IC device can easily detect the abnormality of a system by filtering out the noise from the attack signal.

While the present inventive concept has been particularly shown and described with reference to exemplary embodiments thereof, it will be understood by those of ordinary skill in the art that various changes in forms and details may be made therein without departing from the spirit and scope of the present inventive concept as defined by the following claims.

What is claimed is:

1. An integrated circuit (IC) device comprising:
a detector configured to detect an abnormal condition of the IC device and to generate a detection result as an attack signal; and
a noise filter configured to filter out the attack signal as noise and to generate a filtered attack signal,
wherein the noise filter is configured to filter out the attack signal as noise when the attack signal is not maintained at a first logic level for a reference period and to generate the filtered attack signal when the attack signal is maintained at the first logic level for the reference period.

2. The IC device of claim 1, wherein the noise filter counts the number of pulses of a clock signal while the attack signal is at the first logic level, compares a count result with a reference value, and generates the filtered attack signal based upon a comparison result.

3. The IC device of claim 2, wherein the noise filter comprises:
a counter configured to perform counting with respect to the attack signal at the first logic level based upon the clock signals; and
a comparator configured to compare a count result of the counter with the reference value.

4. An integrated circuit (IC) device comprising:
a detector configured to detect an abnormal condition of the IC device and to generate a detection result as an attack signal; and
a noise filter unit configured to filter out noise from the attack signal and to generate a filtered attack signal,
wherein the noise filter unit is configured to count the number of ripples of the attack signal, to compare a count result with a reference value, and to generate the filtered attack signal based upon a comparison result.

5. The IC device of claim 4, wherein the count result of the noise filter unit is reset when the attack signal is maintained at a first logic level during a reference period.

6. The IC device of claim 5, wherein the first logic level is indicative of attack signal.

7. The IC device of claim 4, wherein the noise filter unit comprises:
an attack signal filtering block configured to count the number of ripples of the attack signal, to compare the count result with the reference value, and to generate the filtered attack signal based upon the comparison result; and
a reset block configured to generate a noise reset signal when the attack signal is at a first logic level during a reference period,
wherein the attack signal filtering block resets the count result based upon the noise reset signal.

8. The IC device of claim 7, wherein the attack signal filtering block comprises:
a first logic unit configured to receive and to perform a logic operation on the attack signal, a clock signal, and a signal inverting a filtered attack signal; and
a noise filter configured to count the number of ripples of an output signal of the first logic unit, to compare the count result with the reference value, and to generate the filtered attack signal based upon the comparison result.

9. The IC device of claim 8, wherein the reset block comprises:
a second logic unit configured to receive and perform a logic operation on a system reset signal, an inverted attack signal, and an inverted filter reset signal; and
a filter reset signal generator configured to generate a filter reset signal when an output signal of the second logic unit is maintained at the first logic level for the reference period.

10. The IC device of claim 9, wherein the reset block further comprises a third logic unit configured to receive and to perform a logic operation on the system reset signal and the inverted filter reset signal.

11. A smart card comprising:
a CPU that controls operations of the smart card;
an interface that communicates data with an external data processing device;
a memory that performs write, read, or verify operations in response to control signals output from the CPU;
peripheral circuitry that processes data to and from the memory; and
an attack signal detector that detect an abnormal condition of the smart card, that generates a detection result as an attack signal, that filters out noise from the attack signal, and that outputs a filtered attack signal
wherein the attack signal detector is configured to filter out the attack signal as noise when the attack signal is not maintained at a first logic level for a reference period or when a value counting the number of ripples of the attack signals less than the reference value.

12. The smart card of claim 11, further comprising a security handler that receives the filtered attack signal from the attack signal detector and that transmits the filtered attack signal to at least one among the interface, the CPU, the peripheral circuit, the memory, and the reset controller through a bus.

13. The smart card of claim 12, further comprising a reset controller that receives the filtered attack signal from the attack signal detector and that determines whether to reset the entire smart card or some portions of the smart card based upon the filtered attack signal.

14. The smart card of claim 11, wherein the smart card is in an electronic system which comprises at least one of a video camera, a television, an MP3 player, a game console, an electronic instrument, a portable terminal, a personal computer, a personal digital assistant, a voice recorder and a personal computer card.

15. The smart card of claim 11, wherein the attack signal detector is further configured to generate the filtered attack signal when the attack signal is maintained at the first logic level for the reference period.
